(19) United States
(12) Patent Application Publication
(10) Pub. No.: US 2025/0391654 A1
(43) Pub. Date: Dec. 25, 2025

(54) FAST CARBON PLUGFILL FOR PATTERNS WITH LARGE CRITICAL DIMENSIONS

(71) Applicant: Applied Materials, Inc., Santa Clara, CA (US)

(72) Inventors: Lihua WU, Santa Clara, CA (US); Ji Ho JANG, Santa Clara, CA (US); Bharati NEELAMRAJU, Sunnyvale, CA (US); Karthiksuresh MENON, Santa Clara, CA (US); Rajaram NARAYANAN, Santa Clara, CA (US); Prashant Kumar KULSHRESHTHA, San Jose, CA (US); Lei HE, Santa Clara, CA (US); Daemian Raj BENJAMIN RAJ, Fremont, CA (US); Sungwon HA, Palo Alto, CA (US)

(21) Appl. No.: 18/753,231

(22) Filed: Jun. 25, 2024

(51) Int. Cl. H01L 21/02; C23C 16/26; C23C 16/509

(52) U.S. Cl. CPC H01L 21/02274; C23C 16/26; C23C 16/509; H01L 21/02115

(57) ABSTRACT

In some embodiments, a method includes positioning a substrate structure into a processing volume of a process chamber. The method further includes flowing a hydrocarbon precursor having C₂H₂ into the processing volume of the processing chamber at a precursor flow rate of about 400 sccm to about 800 sccm. The method further includes flowing an etchant gas having NH₃ into the processing volume of the processing chamber at an etchant gas flow rate of about 0.1 sccm to about 250 sccm. The method further includes providing a high frequency radio frequency (HFRF) power of about 700 W to about 1500 W to the processing volume to generate a RF in the processing volume of the processing chamber. The method further includes forming a carbon based plugfill layer over the surface of the substrate structure and a carbon based plug within the feature of the substrate structure.

### BACKGROUND

### Field

Embodiments of the present disclosure relate to the manufacture of semiconductor components and devices. More specifically, embodiments described herein provide methods of depositing carbon based plugfill layers onto a semiconductor surface and within large critical dimension features.

### Description of the Related Art

In semiconductor processing, devices are being manufactured with continually decreasing feature dimensions. Often, features utilized to manufacture devices at these advanced technology nodes include high aspect ratio structures, and it is often necessary to fill features between circuit elements/structures with a variety of materials. Examples where gapfill material layers are utilized include filling shallow trench isolation (STI), horizontal interconnects, vias between adjacent metal layers, inter-metal dielectric layers (ILD), pre-metal dielectrics (PMD), passivation layers, patterning applications, etc.

Oftentimes a single device or substrate will have multiple features of varying widths (e.g., critical dimensions (CD)) and/or aspect ratios that will need to be filled with a carbon based plugfill material and/or a layer of such material. In some instances, a single device or substrate have one or more large critical dimension (LCD) features (e.g., features including widths greater than about 500 nm and depths of at least about 8 μm). However, conventional chemical vapor deposition (CVD) techniques often experience an overgrowth of material, via a columnar growth profile, at the top of the gap (e.g., overburden regions of the substrate structure) leading to void and dent formation at the surface of the deposited carbon based plugfill layer. Such dents and voids can ultimately lead to device failure.

Accordingly, what is needed in the art are improved methods for forming and/or depositing carbon based plugfill materials onto and within devices having LCD features.

### SUMMARY

Embodiments described herein generally relate to the manufacture of semiconductor components and devices. More specifically, embodiments described herein provide methods of depositing carbon based plugfill layers onto a semiconductor surface and within large critical dimension features.

In some embodiments, a method includes positioning a substrate structure into a processing volume of a process chamber. The substrate structure includes a surface and a feature disposed therein. The method further includes flowing a hydrocarbon precursor having C₂H₂ into the processing volume of the processing chamber at a precursor flow rate of about 400 sccm to about 800 sccm. The method further includes flowing an etchant gas having NH₃ into the processing volume of the processing chamber at an etchant gas flow rate of about 0.1 sccm to about 250 sccm. The method further includes providing a high frequency radio frequency (HFRF) power of about 700 W to about 1500 W to the processing volume to generate a RF plasma from the hydrocarbon precursor and the etchant gas in the processing volume of the processing chamber. The method further includes forming a carbon based plugfill layer over the surface of the substrate structure and a carbon based plug within the feature of the substrate structure.

In some embodiments, a method includes positioning a substrate structure into a processing volume of a process chamber. The substrate structure includes a surface and one or more features disposed therein. At least one of the one or more features includes a large critical dimension (LCD) feature. The method further includes flowing a hydrocarbon precursor having C₂H₂ into the processing volume of the processing chamber at a precursor flow rate of about 400 sccm to about 800 sccm. The method further includes flowing an etchant gas having NH₃ into the processing volume of the processing chamber at an etchant gas flow rate of about 0 sccm to about 250 sccm. The method further includes providing a high frequency radio frequency (HFRF) power of about 700 W to about 1500 W to the processing volume to generate a RF plasma from the hydrocarbon precursor and the etchant gas in the processing volume of the processing chamber. The method further includes forming a carbon based plugfill layer over the surface of the substrate structure and a carbon based plug within at least one of the one or more features of the substrate structure.

In some embodiments, a device includes a substrate structure and one or more features disposed into the substrate structure. At least one of the one or more features includes a large critical dimension (LCD) feature. The device further includes a carbon based plugfill layer disposed over the substrate structure. The carbon based plugfill layer having a dent formation on a surface of the carbon based plugfill layer. The dent formation comprising a dent height of less than about 600 nm. The device further includes a carbon based plug disposed within at least one of the one or more features. The carbon based plug has a plug height of about 1000 nm to about 2500 nm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 is a schematic cross-sectional view of a process chamber, according to an embodiment.

FIG. 2 is a schematic block diagram of a method for forming a carbon based plugfill layer, according to an embodiment.

FIG. 3A is a schematic cross-sectional view of a substrate structure, according to an embodiment.

FIG. 3B is a schematic cross-sectional view of a substrate structure, according to an embodiment.

FIG. 4A is a cross-sectional schematic diagram of a substrate structure, according to an embodiment.

FIG. 4B is a cross-sectional schematic diagram of a substrate structure, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to methods, techniques, and/or parameters to deposit a carbon based plugfill layer over a substrate structure having a LCD feature, such that the surface of the carbon based plugfill layer is smooth and/or substantially free of any dent formation. Conventional deposition techniques and processes implement the use of high activity etchants, which can result in the deposition of a carbon based plugfill layer having a plurality of dent formations of significant dent height on the surface of the carbon based plugfill layer, which may ultimately result in device failure. Process(es) disclosed herein address the issue of dent formation through the use of NH₃ as the etchant gas, as well as an optimized dilution ratio and optimized RF power, to deposit a carbon based plugfill layer with a relatively smooth surface over a substrate structure. Without being bound by theory, the unique etching behavior of NH₃ encourages a granular growth profile of the carbon based plugfill layer during deposition onto the substrate structure and within the features thereof. Such a granular growth profile can limit the carbon growth on the flat overburden regions of the substrate structure. As such, dent formation and/or dent height is significantly reduced and the overall loading of the carbon based plugfill material is lower due to a limited surface reaction rate.

Many of the details, dimensions, angles and other features shown in the figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

Embodiments described herein will be described below in reference to a CVD deposition process that can be carried out using any suitable thin film deposition system. Examples of suitable systems include the CENTURA® systems which may use a DXZ® process chamber, PRECISION 5000@ systems, PRODUCER® systems, PRODUCER® GT™ systems, PRODUCER® XP Precision™ systems, all of which are commercially available from Applied Materials, Inc., of Santa Clara, California. Other chambers, including those from other manufacturers, also benefit from aspects of this disclosure.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment or post-treatment process to polish, etch, reduce, oxidize, hydroxylate, anneal, UV cure, e-beam cure and/or bake the substrate surface.

In addition to film processing directly on the surface of the substrate itself, in the present disclosure, any of the processing operations disclosed may also be performed on an intermediate layer formed on the substrate as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

Carbon-based film deposition has been used to provide gapfill material layers during semiconductor processing through vapor deposition process techniques, such as CVD or plasma enhanced chemical vapor deposition (PECVD). CVD and PECVD utilize a blanket deposition process that generally deposits more gapfill material along a top surface of a feature, where a trench between the features remains void of the gapfill material layer.

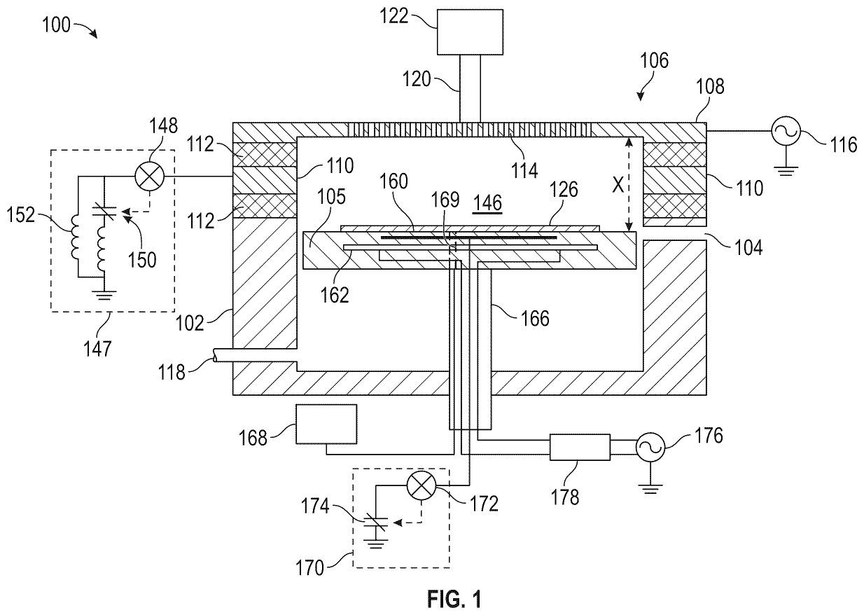

FIG. 1 is a schematic cross sectional view of a process chamber 100 configured according to various embodiments of the present disclosure. By way of example, the embodiment of the process chamber 100 in FIG. 1 is described in terms of a PECVD system, but any other process chamber may fall within the scope of the embodiments, including other plasma deposition chambers or plasma etch chambers. The process chamber 100 includes a chamber body 102, a lid assembly 106, and a substrate support 105. The lid assembly 106 is disposed at an upper end of and is supported by the chamber body 102, and the substrate support 105 is at least partially disposed within the chamber body 102. The chamber body 102, lid assembly 106, and substrate support 105 together define an processing volume 146 within the process chamber 100 in which a substrate may be processed. The processing volume 146 may be accessed through a port 104 formed in the chamber body 102 that facilitates transfer of a substrate into and out of the processing volume 146 of the process chamber 100.

The lid assembly 106 includes a gas distributor 108, an optional modulation electrode 110, and insulators 112. The insulator 112, which may be a dielectric material such as a ceramic or metal oxide, for example aluminum oxide and/or aluminum nitride, contacts an optional modulation electrode 110 and separates the modulation electrode 110 electrically and thermally from the gas distributor 108 and from the chamber body 102. The gas distributor 108 (e.g., showerhead) has passages 114 therethrough for admitting process gas into the processing volume 146. A pair of insulators (e.g., annular insulators) are disposed between the gas distributor 108 and the modulation electrode 110. The modulation electrode 110 is annular and circumscribes the processing volume 146. It is contemplated that the modulation electrode may be omitted from the process chamber 100.

Process gases (e.g., one or more precursor and optionally one or more inert carrier gas) may be provided through the conduit 120 from a gas source 168 to be introduced into the process chamber 100. The processing gas from the conduit 120 enters the processing volume 146 through the passages 114 in the gas distributor 108 such that the processing gas is uniformly distributed in the processing volume 146. In one embodiment, the passages 114 in the gas distributor 108 may be radially distributed and gas flow to each of the passages 114 may be separately controlled to further facilitate gas uniformity within the processing volume 146.

The processing gases can be evacuated from the processing volume 146 through an outlet 118, which may be located at any convenient location along the chamber body 102. In some embodiments, the outlet 118 may be associated with a vacuum pump (not shown) fluidly coupled to the processing volume 146. The vacuum pump may be part of the gas and pressure control system of the processing chamber 100.

In some embodiments, portions of the gas distributor 108 may be heated using a resistive heater (not shown) or thermal fluid disposed in a conduit (not shown) through a portion of the gas distributor 108 or otherwise in direct contact or thermal contact with the gas distributor 108. The conduit may be disposed through an edge portion of the gas distributor 108 to avoid disturbing the gas flow function of the gas distributor 108. Heating the edge portion of the gas distributor 108 may be useful to reduce the tendency of the edge portion of the gas distributor 108 to be a heatsink within the process chamber 100.

In some embodiments, the walls of the chamber body 102 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

In some embodiments, the gas distributor 108 may be coupled to a RF power source 116, such as a RF generator, as shown in FIG. 1. DC power, pulsed DC power, and pulsed RF power source may alternatively be used. In other embodiments, the gas distributor 108 may be coupled to ground. The RF power source 116 is electrically connected to the gas distributor 108 and is configured to apply a RF potential to the gas distributor 108 to facilitate the generation of plasma in the processing volume 146. In some embodiments, the RF power source 116 may be a high frequency RF power source (“HFRF power source”) capable of generating an HFRF power at a frequency of about 10 MHz to about 40 MHZ, such as about 20 MHz to about 22 MHZ, alternatively about 22 MHz to about 24 MHZ, alternatively about 24 MHz to about 26 MHZ, alternatively about 26 MHz to about 28 MHZ, alternatively about 28 MHz to about 30 MHz. In other embodiments, the RF power source 116 may be a low frequency RF power source (“LFRF power source”) capable of generating an LFRF power at a frequency of about 300 KHz. The LFRF power source can provide both low frequency generation and fixed match elements. The HFRF power source can be designed for use with a fixed match and can regulate the power delivered to the load, eliminating concerns about forward and reflected power.

In further embodiments, an additional power source (not shown) may be added with the RF power source 116 to provide a dual RF power source to the process chamber 100. The modulation electrode 110 may be coupled to a tuning circuit 144 that controls an impedance of an electrical path from the modulation electrode 110 to an electrical ground. The tuning circuit 144 comprises an electronic sensor 148 and an electronic controller, which may be a variable capacitor 150 as shown that is controllable by the electronic sensor 148. The tuning circuit 144 may be an LLC circuit comprising one or more inductors 152. The electronic sensor 148 may be a voltage or current sensor and may be coupled to the variable capacitor 150 to afford a degree of closed-loop control of plasma conditions inside the processing volume 146. In some embodiments, the tuning circuit 144 may be any circuit that features a variable or controllable impedance under the plasma conditions present in the processing volume 146 during processing

The substrate support 105 may be disposed within the process chamber 100. The substrate support 105 may support a substrate 126 during processing. A first electrode 160 and a second electrode 162 are disposed in and/or on the substrate support 105. Further, in some embodiments, a heater element (not shown) may be embedded in the substrate support 105. The heater element can be operable to controllably heat the substrate support 105 and the substrate 126 positioned thereon to a target temperature, such as to maintain the substrate 126 at a temperature in a range from about 350° C. to about 600° C.

The substrate support 105 is coupled to a shaft 166 for support. The shaft 166 can provide a conduit from a gas source 168 and electrical and temperature monitoring leads (not shown) between the substrate support 105 and other components of the process chamber 100. In some examples, a purge gas may be provided from the gas source 168 to the backside of the substrate 126 through one or more purge gas inlets 169 connected to the substrate support 105. The purge gas flowed toward the backside of the substrate 126 can help prevent particle contamination caused by deposition on the backside of the substrate 126. The purge gas may also be used as a form of temperature control to cool the backside of the substrate 126. Although not illustrated, the shaft 166 may be coupled to an actuator (not shown) which extends through a centrally-located opening formed in a bottom of the chamber body 102. The actuator may be flexibly sealed to the chamber body 102 by bellows (not shown) that prevent vacuum leakage from around the shaft 166. The actuator can allow the substrate support 105 to be moved vertically within the chamber body 102 between a process position and a lower, transfer position. The transfer position is slightly below the port 104 in the chamber body 102. In operation, the substrate support 105 may be elevated to a position in close proximity to the lid assembly 106 for processing.

The first electrode 160 may be embedded within the substrate support 105 or coupled to a surface of the substrate support 105. The first electrode 160 may be a plate, a perforated plate, a mesh, a wire screen, or any other distributed arrangement. The first electrode 160 may be a tuning electrode and may be coupled to a tuning circuit 170. The tuning circuit 170 may have an electronic sensor 172 and an electronic controller, such as a variable capacitor 174 electrically connected between the first electrode 160 and an electrical ground. The electronic sensor 172 may be a voltage or current sensor and may be coupled to the variable capacitor 174 to provide further control over plasma conditions in the processing volume 146.

The second electrode 162, which may be a bias electrode and/or an electrostatic chucking electrode, may be coupled to the substrate support 105. The second electrode 162 may be coupled to a bias power source 176 through an impedance matching circuit 178. The bias power source 176 may be DC power, pulsed DC power, RF power, pulsed RF power, or a combination thereof.

In operation, the substrate 126 is disposed on the substrate support 105, and process gases are flowed through the lid assembly 106 according to any desired flow plan. Electric power is coupled to the gas distributor to establish a plasma in the processing volume 146. The substrate 126 may be subjected to an electrical bias using the bias power source 376, if desired.

Upon energizing a plasma in the processing volume 146, a potential difference is established between the plasma and the modulation electrode 110. A potential difference is also established between the plasma and the first electrode 160. The variable capacitors 150 and 174 may then be used to adjust the impedances of the paths to an electrical ground represented by the tuning circuits 144 and 170. A set point may be delivered to the tuning circuit 144 and 170 to provide independent control of the plasma density uniformity from center to edge and deposition rate. The electronic sensors may adjust the variable capacitors to maximize deposition rate and minimize thickness non-uniformity independently. The components implemented to control temperature and uniformity of the plasma, among others, can permit deposition of a highly conformal layer on a substrate being processed, even within small gaps.

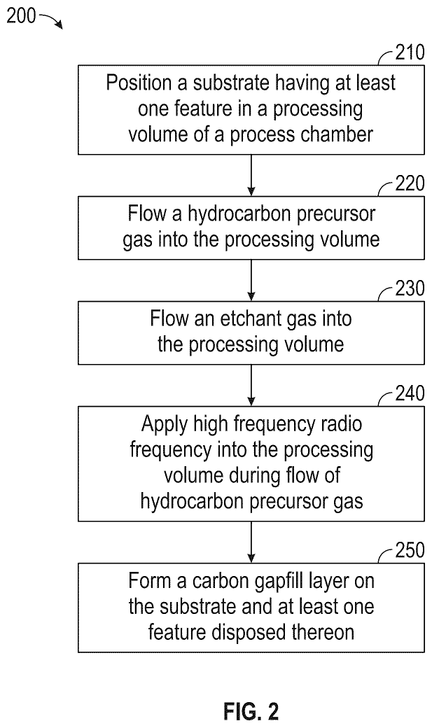

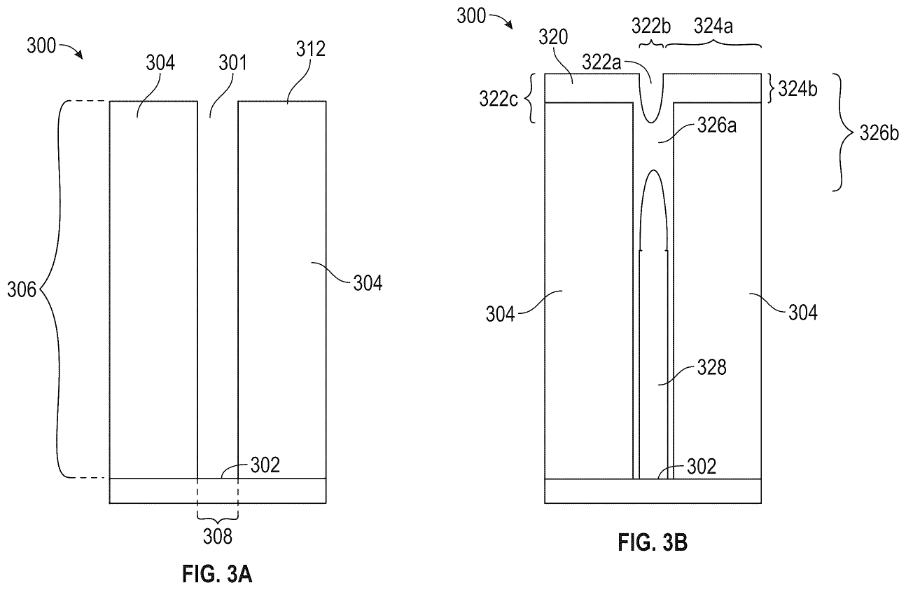

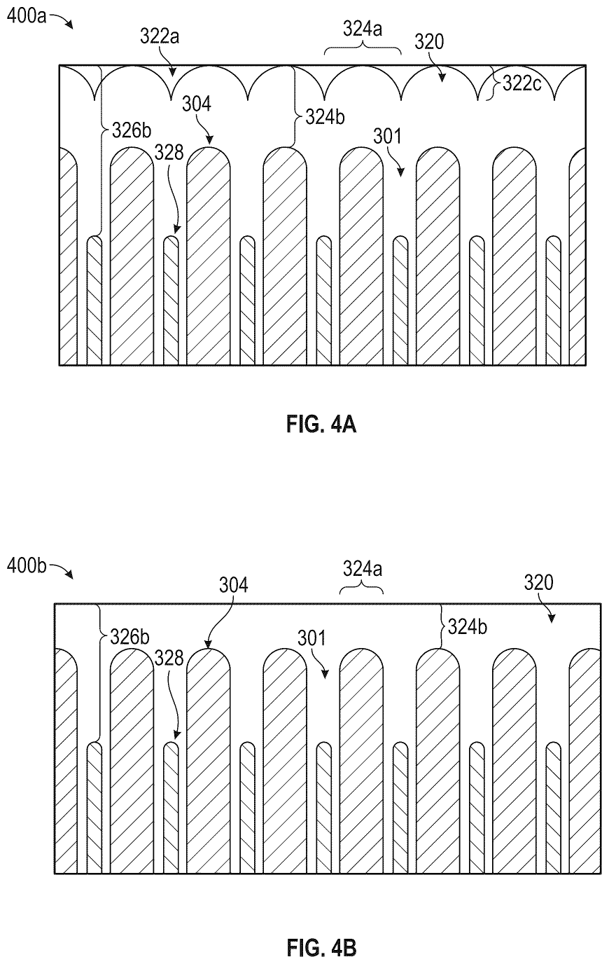

FIG. 2 depicts a process flow diagram of a method 200, for forming a carbon based plugfill layer 320 in a feature 301 formed on a substrate structure 300, in accordance with one or more embodiments of the present disclosure. FIG. 3A and FIG. 3B depict schematic cross-sectional views of a substrate structure 300 illustrating the carbon based plugfill layer 320 formation sequence according to method 200. FIG. 4A-4B depict cross-sectional images of a substrate structure 400 having a carbon based plugfill layer 320 formed thereon using various processing conditions according to method 200. As used in this regard, a feature 301 refers to any intentional surface irregularity, such as gaps, vias, channels, steps, and the like. The shape of a feature 301 can be any suitable shape including, but not limited to, trenches and/or cylindrical vias. A feature 301 may include one or more large critical dimension (LCD) features having two sidewalls 304 and a bottom surface 302, and/or one or more vias having a cylindrical sidewall. Other examples of features 301 may include lines, contact holes, and/or through-holes utilized in a semiconductor, solar, or other electronic devices (e.g., high ratio contact plugs). The features 301 can have any suitable aspect ratio (e.g., ratio of the depth 306 of the feature 301 to the width 308 of the feature 301), such as about 10:1 or greater, such as about 20:1 or greater. In at least one embodiment, the features 301 can have an aspect ratio (e.g., ratio of the depth 306 of the feature 301 to the width 308 of the feature 301) of about 10:1 to about 25:1, such as about 15:1 to about 20:1, alternatively about 10:1 to about 15:1, alternatively about 15:1 to about 20:1, alternatively about 15:1 to about 20:1, alternatively about 20:1 to about 25:1.

Although the method 200 is described below with reference to forming a carbon based plugfill layer between structures formed on a substrate, the method 200 may also be used to advantage in other device manufacturing applications. Further, it should also be understood that the operations depicted in FIG. 2 may be performed simultaneously and/or in a different order than the order depicted in FIG. 2.

The method 200 begins at operation 210 by positioning a substrate structure 300, into a processing volume of a process chamber, such as the processing volume 146 of the process chamber 100 depicted in FIG. 1. The substrate structure 300 may be the substrate 126 depicted in FIG. 1. As show in FIG. 3A and FIG. 3B, the substrate structure 300 includes at least one feature 301, such as a LCD feature formed between a pair of sidewalls 304 disposed on a bottom surface 302 of a substrate structure 300. The LCD feature includes the bottom surface 302 between the sidewalls 304, and an opening between top surfaces 312 of each of the sidewalls 304. In some embodiments, the LCD feature may be a negative feature formed directly in the substrate structure 300. Although FIG. 3A and FIG. 3B show substrate structure 300 having a single LCD feature for illustrative purposes, those skilled in the art will understand that there can be more than one LCD feature, each with the same or different CDs.

The substrate structure 300 may contain one or more materials used in forming semiconductor devices such as metal contacts, trench isolations, gates, bitlines, or any other interconnect features. The substrate structure 300 may comprise one or more metal layers, one or more dielectric materials, semiconductor material, and combinations thereof utilized to fabricate semiconductor devices. For example, the substrate structure 300 may include an oxide material, a nitride material, a polysilicon material, or the like, depending upon application. The substrate structure 300 may be any substrate or material surface upon which film processing is performed. For example, the substrate structure 300 may be a material such as crystalline silicon, silicon oxide, silicon oxynitride, silicon nitride, strained silicon, silicon germanium, tungsten, titanium nitride, doped or undoped polysilicon, doped or undoped silicon wafers and patterned or non-patterned wafers, silicon on insulator (SOI), carbon doped silicon oxides, silicon nitrides, doped silicon, germanium, gallium arsenide, glass, sapphire, low-k dielectrics, and combinations thereof.

In some embodiments, a feature 301 of a substrate structure 300 is a large critical dimension (LCD) feature. An LCD may include a width 308 of the feature 301 greater than about 500 nm, such as greater than about 550 nm, such as greater than about 600 nm. In some embodiments, a feature 301 of the substrate structure 300 includes a depth 306 of the feature 301 of at least about 8 μm, such as at least about 8.5 μm, such as at least about 9 μm.

In at least one embodiment, the substrate structure 300 is transferred into the process chamber 100 and onto the substrate support 105 by any suitable means, such as by substrate transfer port (not shown). The substrate support 105 can be adjusted to a processing position by an actuator (not shown). In some embodiments, the position of the substrate support 105 and the substrate structure 300 in the processing volume 146 may be changed such that the substrate structure 300 may be moved towards the gas distributor 108. The spacing between the bottom surface of the gas distributor 108 and a top surface of the substrate support 105 may be between about 370 mils and about 430 mils, such as about 380 mils to about 420 mils, such as about 390 mils to about 410 mils, alternatively about 370 mils to about 380 mils, alternatively about 380 mils to about 390 mils, alternatively about 390 mils to about 400 mils, alternatively about 400 mils to about 410 mils, alternatively about 410 mils to about 420 mils, alternatively about 420 mils to about 430 mils.

At operation 220, a hydrocarbon precursor gas is flowed into the processing volume 146. In an embodiment, the hydrocarbon precursor gas may be flowed from the gas source 154 into the processing volume 146 through the gas distributor 108. The hydrocarbon precursor may be flowed from the gas source 154 into the processing volume 146 at a flow rate of about 400 sccm to about 800 sccm, such as about 500 sccm to about 700 sccm, such as about 550 sccm to about 650 sccm, alternatively about 400 sccm to about 500 sccm, alternatively about 500 sccm to about 550 sccm, alternatively about 550 sccm to about 600 sccm, alternatively about 600 sccm to about 650 sccm, alternatively about 650 sccm to about 700 sccm, alternatively about 700 sccm to about 800 sccm.

During processing, the hydrocarbon precursor gas may be used to provide a deposition species for forming the carbon plugfill layer. In some embodiment, the hydrocarbon precursor gas includes a hydrocarbon compound having a general formula CₓH_{y}, where x has a range of between 1 and 20 and y has a range of between 1 and 20. Suitable carbon compounds include, for example, methane (CH₄), ethylene (C₂H₄), ethane (C₂H₆), butylenes (C₄H₈), cyclobutane (C₄H₈), and methylcyclopropane (C₄H₈). Suitable butylenes include, for example, 1-Butene, 2-Butene, and isobutylene. In certain embodiments, the hydrocarbon source can be a liquid or gas. In one embodiment, the hydrocarbon precursor gas includes acetylene (C₂H₂). In another embodiment, the hydrocarbon precursor gas includes propylene (C₃H₆). In one example, the hydrocarbon precursor gas is vapor at room temperature, which simplifies the hardware for material metering, control, and delivery to the process chamber.

In some embodiments, the hydrocarbon precursor gas may further include a dilution gas. Suitable dilution gases such as helium (He), argon (Ar), or combinations thereof, may be added to the hydrocarbon precursor gas. Alternatively, dilution gases may not be used during the deposition. In some embodiments, the dilution gas is flowed into the processing volume 146 at a rate of about 0.1 sccm to about 7500 sccm, such as about 1000 sccm to about 5000 sccm, such as about 2000 sccm to about 3000 sccm, alternatively about 0.1 sccm to about 1000 sccm, alternatively about 1000 sccm to about 2000 sccm, alternatively about 2000 sccm to about 2500 sccm, alternatively about 2500 sccm to about 3000 sccm, alternatively about 3000 sccm to about 5000 sccm, alternatively about 5000 sccm to about 7500 sccm. In at least one embodiment, the dilution gas includes He which may be flowed into the processing volume 146 at a rate of about 0.1 sccm to about 330 sccm, such as about 100 sccm to about 300 sccm, such as about 150 sccm to about 250 sccm, alternatively about 0.1 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm, alternatively about 300 sccm to about 330 sccm. In at least one embodiment, the dilution gas includes Ar which may be flowed into the processing volume 146 at a rate of about 4000 sccm to about 7500 sccm, such as about 5000 sccm to about 7000 sccm, such as about 5500 sccm to about 6500 sccm, alternatively about 4000 sccm to about 5000 sccm, alternatively about 5000 sccm to about 5500 sccm, alternatively about 5500 sccm to about 6000 sccm, alternatively about 6000 sccm to about 6500 sccm, alternatively about 6500 sccm to about 7000 sccm, alternatively about 7000 sccm to about 7500 sccm.

At an operation 230, an etchant gas may be flowed into the process chamber 100. In some embodiments, operation 230 is conducted concurrently with operation 220. In some embodiments, operation 230 is conducted subsequent operation 220. In one or more embodiments, the etchant gas may be flowed from the gas source 154 into the processing volume 146 through the gas distributor 108. In some embodiments, the flow of the etchant gas may occur simultaneously to the flow of the hydrocarbon precursor gas. In some embodiments, the etchant gas includes hydrogen gas NH₃, H₂, CO₂, or a combination thereof. In some embodiments, the etchant gas is flowed into the processing volume 146 at a flow rate of about 0.1 sccm to about 1000 sccm, such as about 250 sccm to about 750 sccm, such as about 400 sccm to about 600 sccm, alternatively about 0.1 sccm to about 250 sccm, alternatively about 250 sccm to about 400 sccm, alternatively about 400 sccm to about 500 sccm, alternatively about 500 sccm to about 600 sccm, alternatively about 600 sccm to about 750 sccm, alternatively about 750 sccm to about 1000 sccm. In at least one embodiment, the etchant gas includes NH₃ and is flowed into the processing volume at a flow rate of about 0.1 sccm to about 250 sccm, such as about 50 sccm to about 200 sccm, such as about 100 sccm to about 150 sccm, alternatively about 0.1 sccm to about 50 sccm, alternatively about 50 sccm to about 100 sccm, alternatively about 100 sccm to about 125 sccm, alternatively about 125 sccm to about 150 sccm, alternatively about 150 sccm to about 200 sccm, alternatively about 200 sccm to about 250 sccm. In at least one embodiment, the etchant gas includes H₂ and is flowed into the processing volume at a flow rate of about 0.1 sccm to about 250 sccm, such as about 50 sccm to about 200 sccm, such as about 100 sccm to about 150 sccm, alternatively about 0.1 sccm to about 50 sccm, alternatively about 50 sccm to about 100 sccm, alternatively about 100 sccm to about 125 sccm, alternatively about 125 sccm to about 150 sccm, alternatively about 150 sccm to about 200 sccm, alternatively about 200 sccm to about 250 sccm. The etchant gas may be flowed into the processing volume to provide a hydrocarbon precursor gas to etchant gas ratio of about 2.5:1 to about 6:1, such as about 3:1 to about 5:1, such as about 3.5:1 to about 4.5:1, alternatively about 2.5:1 to about 3:1, alternatively about 3:1 to about 3.5:1, alternatively about 3.5:1 to about 4:1, alternatively about 4:1 to about 4.5:1, alternatively about 4.5:1 to about 5:1, alternatively about 5:1 to about 6:1.

At operation 240, a high frequency RF power is applied to the process chamber 100 to ignite and generate a RF plasma in the processing volume 146. In some embodiments, operation 240 is conducted concurrently with operation 230 and operation 220. In some embodiments, operation 240 is conducted concurrently with operation 230. In some embodiments, operation 240 is conducted subsequent operation 230. The high frequency RF may be provided by an RF power source 116 to facilitate generation of the RF plasma. In an embodiment, the high frequency RF power includes a HFRF power. In certain embodiments, the HFRF power is maintained during the deposition of a hydrocarbon deposition species. In some embodiments, the HFRF power during processing is maintained in a range of about 700 W to about 1500 W, such as about 850 W to about 1350 W, such as about 1000 W to about 1200 W, such as about 1050 W to about 1150 W, alternatively about 700 W to about 850 W, alternatively about 850 W to about 1000 W, alternatively about 1000 W to about 1050 W, alternatively about 1050 W to about 1100 W, alternatively about 1100 W to about 1150 W, alternatively about 1150 W to about 1200 W, alternatively about 1200 W to about 1350 W, alternatively about 1350 W to about 1500 W. In some embodiments, the HFRF power may operate at a frequency of about 10 MHz to about 40 MHz, such as about 15 MHz to about 35 MHz, such as about 20 MHz to about 30 MHz, alternatively about 10 MHz to about 15 MHz, alternatively about 15 MHz to about 20 MHz, alternatively about 20 MHz to about 25 MHZ, alternatively about 25 MHz to about 30 MHz, alternatively about 30 MHz to about 35 MHz, alternatively about 35 MHz to about 40 MHz.

In some embodiments, the pressure within the processing chamber 100 during deposition of the carbon based plugfill material is maintained in a range of about 18 Torr to about 25 Torr, such as about 20 Torr to about 23 Torr, such as about 21 Torr to about 22 Torr, alternatively about 18 Torr to about 20 Torr, alternatively about 20 Torr to about 21 Torr, alternatively about 22 Torr to about 23 Torr, alternatively about 23 Torr to about 25 Torr. In some embodiments, the temperature of the process chamber 100, the substrate structure 300, or both may be maintained may be maintained in the range of about 250° C. to about 600° C., such as about 300° C. to about 550° C., such as about 350° C. to about 450° C., alternatively about 250° C. to about 300° C., alternatively about 300° C. to about 350° C., alternatively about 350° C. to about 400° C., alternatively about 400° C. to about 450° C., alternatively about 450° C. to about 550° C., alternatively about 550° C. to about 600° C.

At operation 250, a carbon based plugfill layer 320 may be formed in the feature 301 on the substrate structure 300 using the RF plasma generated in operation 240, as shown in FIG. 3B. Depositing the carbon based plugfill material onto a substrate structure 300 having a feature 301, such as an LCD, using conventional deposition techniques and process gases (e.g., H₂) may result in the formation of dents 322a at the surface of the carbon based plugfill layer 320. Without being bound by theory, such dent 322a formation can be attributed to the high activity of the etchant used in conventional deposition techniques and process gases. In cases where high activity etchants are used, dents 322a having a greater dent height 322c may be formed at operation 250 resulting in a more columnar growth profile of the carbon based plugfill layer 320. The columnar growth profile can lead to faster deposition rates of the carbon based plugfill layer 320 at the flat overburden regions 324a (e.g., increased thickness 324b of the carbon based plugfill layer 320 of the flat overburden region 324a) of the substrate structure 300 and higher loading of the carbon based plugfill material onto the substrate structure 300 and/or within features 301 of the substrate structure 300. Such increased material loading and dent height 322c may result in device failure.

In some embodiments, operation 250 is conducted using an etchant gas composition having a lower etchant activity, an optimized RF, and an optimized dilution ratio. In one or more embodiments, the etchant gas composition having a lower etchant activity includes NH₃. As such, NH₃ is co-flown with the hydrocarbon precursor (e.g., C₂H₂) at an optimized ratio (e.g., dilution ratio) into the processing chamber 100 (as described in operations 220 and 230) at a relatively high pressure and optimized RF power to deposit a carbon based plugfill layer 320 having a reduced dent height 322c onto the substrate structure 300. Without being bound by theory, the unique etching behavior of NH₃ encourages a granular growth profile of the carbon based plugfill layer 320 during deposition, which limits the carbon growth on the flat overburden regions 324a (e.g., decreased thickness 324b of the carbon based plugfill layer 320 of the flat overburden region 324a) of the substrate structure 300. As such, the dent height 322c is significantly reduced and the overall loading of the carbon based plugfill material is lower due to a limited surface reaction rate.

In some embodiments, the carbon based plugfill material is deposited as a carbon based plugfill layer 320 onto the substrate structure 300 and/or into the features 301 thereof at a rate of about 10 nm/min to about 40 nm/min, such as about 15 nm/min to about 35 nm/min, such as about 20 nm/min to about 30 nm/min, alternatively about 10 nm/min to about 15 nm/min, alternatively about 15 nm/min to about 20 nm/min, alternatively about 20 nm/min to about 25 nm/min, alternatively about 25 nm/min to about 30 nm/min, alternatively about 30 nm/min to about 35 nm/min, alternatively about 35 nm/min to about 40 nm/min. In some embodiments, the surface of the carbon based plugfill layer 320 is smooth and substantially free of any dents 322a. In some embodiments, the surface of the carbon based plugfill layer 320 includes one or more dents 322a. In some embodiments, the surface of the carbon based plugfill layer 320 includes a surface density of the one or more dents 322a (e.g., number of dents per unit are of the surface of the carbon based plugfill layer 320) of about 0.2 dents/μm² to about 4 dents/μm², such as about 0.5 dents/μm² to about 3 dents/μm², such as about 1 dents/μm² to about 2 dents/μm², alternatively about 0.2 dents/μm² to about 0.5 dents/μm², alternatively about 0.5 dents/μm² to about 1 dents/μm², alternatively about 1 dents/μm² to about 1.5 dents/μm², alternatively about 1.5 dents/μm² to about 2 dents/μm², alternatively about 2 dents/μm² to about 3 dents/μm², alternatively about 3 dents/μm² to about 4 dents/μm². In at least one embodiment, a dent 322a present on the surface of the carbon based plugfill layer 320 includes a dent height 322c of about 300 nm to about 600 nm, such as about 350 nm to about 550 nm, such as about 400 nm to about 500 nm, alternatively about 300 nm to about 350 nm, alternatively about 350 nm to about 400 nm, alternatively about 400 nm to about 450 nm, alternatively about 450 nm to about 500 nm, alternatively about 500 nm to about 550 nm, alternatively about 550 nm to about 600 nm. In some embodiments, the one or more dents 322a present on the surface of the carbon based plugfill layer 320 include an average dent height 322c of about 300 nm to about 600 nm, such as about 350 nm to about 550 nm, such as about 400 nm to about 500 nm, alternatively about 300 nm to about 350 nm, alternatively about 350 nm to about 400 nm, alternatively about 400 nm to about 450 nm, alternatively about 450 nm to about 500 nm, alternatively about 500 nm to about 550 nm, alternatively about 550 nm to about 600 nm.

In some embodiments, the carbon based plugfill material is deposited as a carbon based plugfill layer 320 into a feature 301 the substrate structure 300 to form a plug 326a having a plug height 326b (e.g., measure as the distance between the top of the gap 328 formed form the plugged feature and the surface of the carbon based plugfill layer 320) of about 1000 nm to about 2500 nm, such as about 1250 nm to about 2250 nm, such as about 1500 nm to about 2000 nm, alternatively about 1000 nm to about 1250 nm, alternatively about 1250 nm to about 1500 nm, alternatively about 1500 nm to about 1750 nm, alternatively about 1750 nm to about 2000 nm, alternatively about 2000 nm to about 2250 nm, alternatively about 2250 nm to about 2500 nm. In some embodiments, the carbon based plugfill material is deposited as a carbon based plugfill layer 320 into the features 301 the substrate structure 300 to form one or more plug(s) 326a having an average plug height 326b of about 1000 nm to about 2500 nm, such as about 1250 nm to about 2250 nm, such as about 1500 nm to about 2000 nm, alternatively about 1000 nm to about 1250 nm, alternatively about 1250 nm to about 1500 nm, alternatively about 1500 nm to about 1750 nm, alternatively about 1750 nm to about 2000 nm, alternatively about 2000 nm to about 2250 nm, alternatively about 2250 nm to about 2500 nm.

FIG. 4A shows a side cross-sectional view of a device 400a formed from the method 200, according to an embodiment. Specifically the device 400a was formed from the method 200 using conventional deposition techniques and process gases to provide a carbon based plugfill layer 320 deposited over a substrate structure (e.g., substrate structure 300) and within the features 301 of the substrate structure. As conventionally used in the deposition of carbon based plugfill materials, H₂ was implemented as the etchant gas in the formation of the device 400a. As previously discussed, devices formed from the method 200 using high activity etchants (e.g., H₂) etchants result in the formation of dents 322a at the surface of the carbon based plugfill layer 320, as shown in FIG. 4A.

FIG. 4B shows a side cross-sectional view of a device 400b formed from the method 200, according to an embodiment. Specifically the device 400b was formed from the method 200 using etchant gas composition having NH₃, to provide a lower etchant activity. As such, NH₃ was co-flown with the hydrocarbon precursor (e.g., C₂H₂) at an optimized ratio (e.g., dilution ratio) into the processing chamber 100 (as described in operations 220 and 230) at a relatively high pressure and optimized RF power to deposit a carbon based plugfill layer 320 onto a substrate structure (e.g., substrate structure 300). As can be observed in FIG. 4B, the surface of the carbon based plugfill layer 320 is substantially free of dents 322a. Furthermore, the device 400b exhibits a thickness 324b of the carbon based plugfill layer 320 disposed over the flat overburden region 324a of the substrate structure significantly less than that the device 400a, shown in FIG. 4A.

Overall, the present disclosure provides methods, techniques, and/or parameters to deposit a carbon based plugfill layer over a substrate structure having a LCD feature, such that the surface of the carbon based plugfill layer is smooth and/or substantially free of any dent formation. As previously described, conventional deposition techniques and processes implement the use of high activity etchants within the etchant gas composition. The use of such high activity etchants can result in the deposition of a carbon based plugfill layer having a plurality of dent formations of significant dent height on the surface of the carbon based plugfill layer, which may ultimately result in device failure. As such, the process(es) disclosed herein implement the use of NH₃ as the etchant gas, as well as an optimized dilution ratio and optimized RF power, to deposit a carbon based plugfill layer with a relatively smooth surface over a substrate structure. Without being bound by theory, the unique etching behavior of NH₃ encourages a granular growth profile of the carbon based plugfill layer during deposition onto the substrate structure and within the features thereof. Such a granular growth profile can limit the carbon growth on the flat overburden regions of the substrate structure. As such, dent formation and/or dent height is significantly reduced and the overall loading of the carbon based plugfill material is lower due to a limited surface reaction rate.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
positioning a substrate structure into a processing volume of a process chamber, the substrate structure comprising a surface and a feature disposed therein;
flowing a hydrocarbon precursor comprising C₂H₂ into the processing volume of the processing chamber at a precursor flow rate of about 400 sccm to about 800 sccm;
flowing an etchant gas comprising NH₃ into the processing volume of the processing chamber at an etchant gas flow rate of about 0.1 sccm to about 250 sccm;
providing a high frequency radio frequency (HFRF) power of about 700 W to about 1500 W to the processing volume to generate a RF plasma from the hydrocarbon precursor and the etchant gas in the processing volume of the processing chamber;
forming a carbon based plugfill layer over the surface of the substrate structure and a carbon based plug within the feature of the substrate structure.

2. The method of claim 1, wherein the surface of the carbon based plugfill layer is substantially free of dents.

3. The method of claim 1, wherein the carbon based plugfill layer comprises a dent formed on the surface of the carbon based plugfill layer, the dent comprising a dent height of about 300 nm to about 600 nm.

4. The method of claim 1, wherein the hydrocarbon precursor and the etchant gas are co-flown into the processing volume of the processing chamber to provide a hydrocarbon precursor gas to etchant gas ratio of about 2.5:1 to about 6:1.

5. The method of claim 1, wherein the HFRF is operated at a frequency of about 10 MHz to about 40 MHz.

6. The method of claim 1, wherein the processing chamber is maintained at a pressure of about 18 Torr to about 25 Torr during the formation of the carbon based plugfill layer.

7. The method of claim 1, wherein the carbon based plugfill layer is deposited over the surface of the substrate structure at a deposition rate of about 10 nm/min to about 40 nm/min.

8. The method of claim 1, wherein the hydrocarbon precursor further comprises a dilution gas, the dilution gas being selected from the group consisting of He, Ar, and combinations thereof.

9. The method of claim 8, wherein the dilution gas is flown into the processing volume of the processing chamber at a flow rate of about 4000 sccm to about 7500 sccm.

10. A method, comprising:
positioning a substrate structure into a processing volume of a process chamber, the substrate structure comprising a surface and one or more features disposed therein, at least one of the one or more features comprising a large critical dimension (LCD) feature;
flowing a hydrocarbon precursor comprising C₂H₂ into the processing volume of the processing chamber at a precursor flow rate of about 400 sccm to about 800 sccm;
flowing an etchant gas comprising NH₃ into the processing volume of the processing chamber at a etchant gas flow rate of about 0 sccm to about 250 sccm;
providing a high frequency radio frequency (HFRF) power of about 700 W to about 1500 W to the processing volume to generate a RF plasma from the hydrocarbon precursor and the etchant gas in the processing volume of the processing chamber;
forming a carbon based plugfill layer over the surface of the substrate structure and a carbon based plug within at least one of the one or more features of the substrate structure.

11. The method of claim 10, the LCD feature comprises a width greater than about 500 nm and a depth of at least 8 μm.

12. The method of claim 10, wherein the surface of the carbon based plugfill layer is substantially free of dents.

13. The method of claim 10, wherein the carbon based plugfill layer comprises a dent formed on the surface of the carbon based plugfill layer, the dent comprising a dent height of about 300 nm to about 600 nm.

14. The method of claim 10, wherein the hydrocarbon precursor and the etchant gas are co-flown into the processing volume of the processing chamber to provide a hydrocarbon precursor gas to etchant gas ratio of about 2.5:1 to about 6:1.

15. The method of claim 10, wherein the HFRF is operated at a frequency of about 10 MHz to about 40 MHz.

16. The method of claim 10, wherein the processing chamber is maintained at a pressure of about 18 Torr to about 25 Torr during the formation of the carbon based plugfill layer.

17. The method of claim 10, wherein the carbon based plugfill layer is deposited over the surface of the substrate structure at a deposition rate of about 10 nm/min to about 40 nm/min.

18. The method of claim 10, the hydrocarbon precursor further comprises a dilution gas, the dilution gas being selected from the group consisting of He, Ar, and combinations thereof.

19. The method of claim 18, wherein the dilution gas is flown into the processing volume of the processing chamber at a flow rate of about 4000 sccm to about 7500 sccm.

20. A device, comprising:
a substrate structure;
one or more features disposed into the substrate structure, at least one of the one or more features comprising a large critical dimension (LCD) feature;
a carbon based plugfill layer disposed over the substrate structure, the carbon based plugfill layer having a dent formation on a surface of the carbon based plugfill layer, the dent formation comprising a dent height of less than about 600 nm; and
a carbon based plug disposed within at least one of the one or more features, the carbon based plug comprising a plug height of about 1000 nm to about 2500 nm.
